(19) United States
(12) Patent Application Publication
(10) Pub. No.: US 2025/0178884 A1
(43) Pub. Date: Jun. 5, 2025

(54) MEMS CANTILEVER-ENCLOSURE SPACING

(71) Applicant: Soundskrit Inc., Montreal (CA)

(72) Inventors: Yuhai Mei, Ann Arbor, MI (US); Alena Gracheva, Montreal (CA); Mohamed El Badawe, Montreal (CA); Carly Stalder, Montreal (CA)

(21) Appl. No.: 18/960,869

(22) Filed: Nov. 26, 2024

Related U.S. Application Data
(60) Provisional application No. 63/603,433, filed on Nov. 28, 2023.

(51) Int. Cl. B81B 3/00; H04R 1/22; H04R 1/32; H04R 19/04

(52) U.S. Cl. CPC B81B 3/0056; H04R 1/222; H04R 1/326; H04R 19/04; B81B 2201/0257; B81B 2203/0118; B81B 2203/0127; B81B 2203/0136; B81B 2203/0315; B81B 2203/0353; H04R 2201/003

(57) ABSTRACT

A microphone device includes a substrate, a microelectromechanical system (MEMS) transducer supported by the substrate, the MEMS transducer including a cantilever, the cantilever having a length, and an enclosure structure that encapsulates the MEMS transducer. A spacing between the cantilever and the enclosure structure is greater than the length of the MEMS transducer.

### CROSS-REFERENCE TO RELATED APPLICATION

This application claims the benefit of U.S. provisional application entitled “MEMS Cantilever-Enclosure Spacing,” filed Nov. 28, 2023, and assigned Ser. No. 63/603,433, the entire disclosure of which is hereby expressly incorporated by reference.

### BACKGROUND OF THE DISCLOSURE

### Field of the Disclosure

The disclosure relates generally to microelectromechanical system (MEMS) microphones.

### Brief Description of Related Technology

Some microelectromechanical system (MEMS) microphones utilize cantilever-like transducers in order to sense the incoming sound. Unlike traditional omnidirectional microphone transducers, which use plates anchored on all sides and are often relatively stiff, cantilever-based MEMS transducers are often much more compliant. As a result, for a given sound pressure, the cantilever may deflect more than traditional omnidirectional microphone transducers.

In some scenarios, a microphone may experience strong flows of air (e.g., when the microphone is cleaned with an air gun). In these instances, if a cantilever beam of a MEMS transducer is sufficiently compliant, the cantilever beam may deflect at an angle of at or near 90 degrees, e.g., extend vertically. Additionally, the cantilever beam may experience relatively high-frequency vibration along the direction in which the beam bends, and/or twisting along the cross-section of the beam.

### SUMMARY OF THE DISCLOSURE

In accordance with one aspect of the disclosure, a microphone device includes a substrate, a microelectromechanical system (MEMS) transducer supported by the substrate, the MEMS transducer including a cantilever, the cantilever having a length, and an enclosure structure that encapsulates the MEMS transducer. A spacing between the cantilever and the enclosure structure is greater than the length of the MEMS transducer.

In accordance with another aspect of the disclosure, a microphone device includes a substrate, a microelectromechanical system (MEMS) transducer supported by the substrate, the MEMS transducer including a cantilever, the cantilever having a length, and a lid that encapsulates the MEMS transducer. The cantilever is spaced apart from the lid by a distance. The distance is greater than the length of the MEMS transducer.

In accordance with yet another aspect of the disclosure, a microphone device includes a substrate, a microelectromechanical system (MEMS) transducer supported by the substrate, the MEMS transducer including a cantilever, the cantilever having a length, and a lid that encapsulates the MEMS transducer. A clearance between the cantilever and the lid is greater than the length of the MEMS transducer.

In connection with any one of the aforementioned aspects, the devices and/or methods described herein may alternatively or additionally include or involve any combination of one or more of the following aspects or features. The spacing corresponds with a distance between a biased position of the MEMS transducer and the enclosure structure. The microphone device further includes a first sound port and a second sound port, the first and second sound ports being in acoustic communication with the MEMS transducer. The substrate includes the first sound port. The enclosure structure includes the second sound port. The first and second sound ports are aligned with one another. The substrate and the enclosure define a cavity in which the MEMS transducer is disposed. The first and second sound ports are disposed on opposing sides of the cavity. The length of the MEMS transducer is such that the MEMS transducer has a resonant frequency between about 1 kHz and about 5 kHz. The length of the MEMS transducer falls in a range from about 300 microns to about 500 microns. The MEMS transducer has a thickness less than about 2 microns. The MEMS transducer includes a porous plate. The MEMS transducer further includes a plurality of fingers extending from the porous plate. The enclosure structure includes a lid. The MEMS transducer is configured as a directional transducer.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 is a schematic, sectional view of a microphone device having transducer-enclosure spacing in accordance with one example.

FIG. 2A is a schematic, plan view of a microphone device having transducer-enclosure spacing in accordance with one example.

FIG. 2B is a schematic, bottom view of the microphone device of FIG. 2A.

The embodiments of the disclosed devices may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Microphone devices having sufficient spacing between a MEMS transducer and an enclosure structure are described. The spacing is sufficient to avoid or prevent contact between a cantilever of the MEMS transducer and the enclosure structure. For instance, the spacing may be greater than a length of the cantilever. In some cases, the enclosure structure is or includes a lid. As described herein, the spacing may correspond with a distance between an initial position of the MEMS transducer (e.g., cantilever beam) and the lid or other enclosure structure. The initial position of the MEMS transducer may correspond with a biased position or an unbiased position.

If there is not enough clearance between the lid of the microphone and the cantilever beam, then the cantilever beam may contact the microphone lid, thereby generating excessive forces on at least portions of the MEMS transducer. As a result, the MEMS transducer may be damaged. For example, a portion of the MEMS transducer may break.

Although described in connection with cantilever beams, the transducer-encapsulation spacing of the disclosed devices may be used in connection with a wide variety of transducer and microphone configurations. For instance, other types of cantilever-based transducers may be used. The disclosed microphones are also not limited to directional microphones. Thus, the packaging architectures described herein may be useful in connection with, for instance, omnidirectional microphones. The configuration, construction, and other characteristics of the enclosure structure may also vary from the examples shown and described.

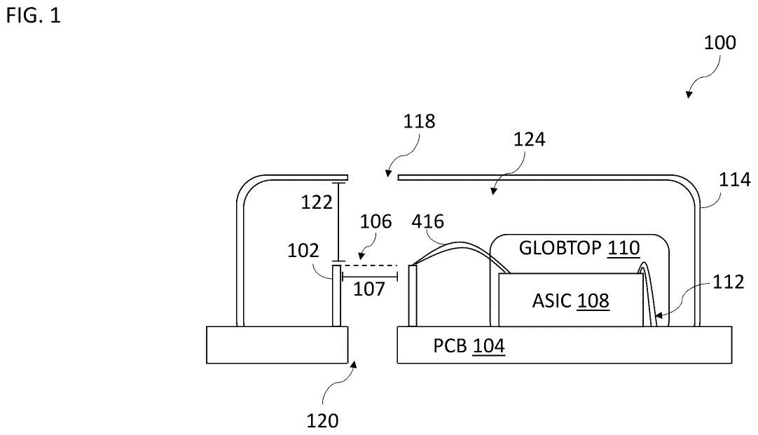

FIG. 1 depicts a device 100 having a lid and corresponding transducer-enclosure spacing in accordance with one example. The device includes a MEMS transducer 102 attached to or otherwise supported by a substrate 104. In this example, the substrate 104 is or includes a printed circuit board (PCB). The MEMS transducer is or includes a flexible cantilever, or electrode, 106 with a length 107. The substrate 104 may be or include a printed circuit board with one or multiple layers. The device 100 includes an application-specific integrated circuit (ASIC) 108. The ASIC 108 is configured to read out the electrical signal from the MEMS transducer 102 and is covered by a protective gloptop 110. The ASIC 108 is also attached to the substrate 104 and electrically connected to conductive traces on the substrate by wire bonds 112. Both the MEMS transducer 102 and the ASIC 108 are encapsulated by a lid or other enclosure 114. The lid 114 may be composed of, or otherwise include, a metal material. Additional or alternative materials may be used. For instance, the lid 114 or other enclosure may be provided by another PCB or other substrate.

The MEMS transducer 102 and the ASIC 108 may be electrically connected by wire bonds 116, either to each other, or directly to the substrate 104. The MEMS transducer 102, the ASIC 108, and the lid 114 may alternatively or additionally be attached using other arrangements or structures. For instance, the MEMS transducer 102 may be attached to the device PCB 104 using flip chip technology.

The MEMS transducer 102 may be or include a composite structure. For instance, in some cases, the MEMS transducer 102 may include one or more conductive layers and one or more dielectric layers. In one example, the MEMS transducer 102 includes a conductive layer disposed between a pair of dielectric layers. The conductive layer(s) may be composed of, or otherwise include, polysilicon. The dielectric layer(s) may be composed of, or otherwise include, silicon nitride. The dielectric layers on either side of the conductive layer may have equal thicknesses.

In some cases, the device 100 may be configured as, or otherwise include, a microphone. In the example of FIG. 1, the device 100 includes a top sound port 118 embedded or otherwise disposed in the lid 114 of the device. The device 100 may also have a bottom sound port 120 embedded or otherwise disposed in the device PCB 104. The two sound ports 118 and 120 are provided to allow ambient sound to couple into the device 100. The two sound ports 118 and 120 are thus in acoustic communication with the MEMS transducer 106. As shown in the example of FIG. 1, the cantilever 106 of the device 100 may be disposed in a cavity 124 between the top sound port 118 and the bottom sound port 120. The sound ports 118, 120 may or may not be aligned or disposed on opposing sides of the cavity 124 as shown. The location, configuration, and other characteristics of the sound ports 118, 120 may vary. For instance, in other cases, the device 100 may only have a single sound port either embedded or otherwise disposed in the lid 114 or the PCB 104.

As sound or air travels along a direction parallel to the axis connecting the opposing sound ports 118 and 120, the air excites the MEMS transducer 102 and causes the cantilever 106 to vibrate. In some examples, the cantilever 106 is configured such that the cantilever 106 has a resonance frequency in the audio spectrum. In some instances, the resonance of the cantilever 106 may be set to frequencies most useful for voice capture, such as frequencies between about 3 kHz and about 5 kHz. In other examples, the cantilever 106 may have a resonance between about 1 kHz and about 3 kHz.

The resonant frequency of the cantilever 106 may be lower than those of traditional MEMS microphones that have a resonance above 20 kHz. A cantilever with a lower resonance (e.g., between about 1 kHz and about 5 kHz) may be achieved by making the cantilever 106 long. As the length 107 of the cantilever 106 increases, the resonant frequency decreases. However, the longer the cantilever 106, the more compliant the cantilever 106 is, and the more the cantilever 106 may bend when exposed to a strong flow of air. In some cases, if the flow of air is strong enough, the cantilever 106, which originally extends horizontally, may bend so that the cantilever 106 extends vertically.

The lid 114 of device 100 defines or establishes a spacing or distance 122 between the top surface of the MEMS transducer 102 and the lid 114. In the example of FIG. 1, the spacing 122 is at least as large as the length 107 of cantilever 106. This spacing ensures that, as the cantilever 106 deflects vertically when exposed to strong flows of air, the cantilever 106 does not collide with the lid 114.

The spacing between the lid 114 or other enclosure structure and the MEMS transducer 102 establishes an interior volume of the device. Increasing the spacing may increase the interior volume. An increased volume may, in turn, modify a resonant frequency associated with the interior volume. In some cases, one or more aspects or elements of the device may be sized, positioned, or otherwise configured to avoid having the resonant frequency associated with the interior volume fall within a frequency range of interest. For instance, the size or positioning of one or both of the sound ports may be selected or adjusted to shift the resonant frequency out of the range of interest.

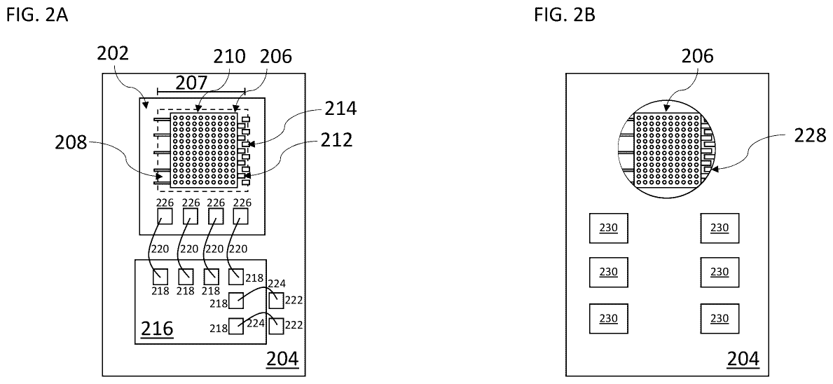

FIG. 2A depicts a top view of the inside of a MEMS microphone in accordance with one example having a lid or transducer-enclosure spacing as described above in connection with FIG. 1. A substrate (e.g., a silicon MEMS die) 202 is mounted on or otherwise supported by a printed circuit board (PCB) 204 using an adhesive layer or any other attachment arrangement or structure. A cantilever 206 is patterned and etched in the substrate 202 and suspended over a cavity 208 in the substrate 202. The cavity 208 in the substrate may be formed via deep reactive ion etching. The cantilever 206 is configured such that the cantilever 206 vibrates when exposed to an external stimulus such as air flow through the cavity 208. The cantilever 206 has a length 207 and includes a plate 210 and fingers 212. As shown in FIG. 2A, the fingers 212 extend outward from the plate 210. As the cantilever 206 vibrates, so do the plate 210 and fingers 212. Etched into the substrate 202 are also fixed fingers 214. As air flows through the cavity 208, the fixed fingers 214 do not move relative to the fingers 212. This creates a change in capacitance in the MEMS microphone and thus generates a signal.

The cantilever 206 may be configured as, or otherwise include, one or multiple porous plates. In other examples, the cantilever 206 may include an array of beams with air gaps between them. The cantilever 206 may be constructed or configured such that it is relatively thin (e.g., sufficiently thin to attain an amount of compliance suitable for resonance at a useful frequency). For example, the thickness of the cantilever 206 may be less than about 2 um or about 1 um. In some instances, the cantilever 206 may have a length 207 and thickness such that it has a resonance around 4 kHz. In some instances, the cantilever 206 may have a length 207 that falls in a range from about 300 um to about 500 um.

An application specific circuit (ASIC) 216 is also mounted on or otherwise supported by the PCB 204 through an adhesive layer or any other attachment arrangement or structure. The ASIC contains one or more bond pads 218 and is electrically connected to the cantilever 206 through wirebonds 220 and MEMS bond pads 226. The PCB may also include one or more bond pads 222. The ASIC 216 may be connected to the bond pads 222 through wire bonds 224. The ASIC 216 takes an electrical signal generated by the MEMS cantilever 206 and amplifies the signal. In some examples, the ASIC 216 may provide one or bias voltages to the MEMS cantilever 206. Power may be provided to the ASIC 216 externally through one or more bond pads 222, and the output of the ASIC 216 may be transmitted to an external processor through one or more of the pond pads 222.

FIG. 2B depicts a bottom view of the MEMS microphone of FIG. 2A. The PCB 204 has a hole, or sound port, 228 over which the MEMS cantilever 206 and cavity 208 are suspended. On the bottom of the PCB 204 are one or more electrical pads 230. In some examples the pads 230 may be soldered on to an external PCB not drawn and connect the MEMS cantilever 206 and ASIC 216 to external electrical components. The sound port 228 may have a circular, conical, elliptical, rectangular, hexagonal, or any other geometric profile,

The term “about” is used herein in a manner to include deviations from a specified value that would be understood by one of ordinary skill in the art to effectively be the same as the specified value due to, for instance, the absence of appreciable, detectable, or otherwise effective difference in operation, outcome, characteristic, or other aspect of the disclosed methods and devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A microphone device comprising:
a substrate;
a microelectromechanical system (MEMS) transducer supported by the substrate, the MEMS transducer comprising a cantilever, the cantilever having a length; and
an enclosure structure that encapsulates the MEMS transducer;
wherein a spacing between the cantilever and the enclosure structure is greater than the length of the cantilever.

2. The microphone device of claim 1, wherein the spacing corresponds with a distance between a biased position of the MEMS transducer and the enclosure structure.

3. The microphone device of claim 1, further comprising a first sound port and a second sound port, the first and second sound ports being in acoustic communication with the MEMS transducer.

4. The microphone device of claim 3, wherein:
the substrate comprises the first sound port; and
the enclosure structure comprises the second sound port.

5. The microphone device of claim 3, wherein the first and second sound ports are aligned with one another.

6. The microphone device of claim 3, wherein:
the substrate and the enclosure define a cavity in which the MEMS transducer is disposed; and
the first and second sound ports are disposed on opposing sides of the cavity.

7. The microphone device of claim 1, wherein the length of the MEMS transducer is such that the MEMS transducer has a resonant frequency between about 1 kHz and about 5 KHz.

8. The microphone device of claim 1, wherein the length of the MEMS transducer falls in a range from about 300 microns to about 500 microns.

9. The microphone device of claim 1, wherein the MEMS transducer has a thickness less than about 2 microns.

10. The microphone device of claim 1, wherein the MEMS transducer comprises a porous plate.

11. The microphone device of claim 10, wherein the MEMS transducer further comprises a plurality of fingers extending from the porous plate.

12. The microphone device of claim 1, wherein the enclosure structure comprises a lid.

13. The microphone device of claim 1, wherein the MEMS transducer is configured as a directional transducer.

14. A microphone device comprising:
a substrate;
a microelectromechanical system (MEMS) transducer supported by the substrate, the MEMS transducer comprising a cantilever, the cantilever having a length; and
a lid that encapsulates the MEMS transducer;
wherein:
the cantilever is spaced apart from the lid by a distance; and
the distance is greater than the length of the cantilever.

15. A microphone device comprising:
a substrate;
a microelectromechanical system (MEMS) transducer supported by the substrate, the MEMS transducer comprising a cantilever, the cantilever having a length; and
a lid that encapsulates the MEMS transducer;
wherein a clearance between the cantilever and the lid is greater than the length of the MEMS transducer.
